(19) United States
(12) Patent Application Publication
(10) Pub. No.: US 2007/0047690 A1
(43) Pub. Date: Mar. 1, 2007

(54) Phase locked loop circuit and phase locked loop control method

(75) Inventors: Hui Zhao, Suwon-si (KR); Hyun-soo Park, Seoul (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/484,621

(22) Filed: Jul. 12, 2006

(30) Foreign Application Priority Data
Aug. 29, 2005 (KR) 2005-79448

(51) Int. Cl. H03D 3/24

(52) U.S. Cl. 375/376

(57) ABSTRACT

A phase locked loop circuit and a phase locked loop control method in an optical disc reproducing system having a high ISI condition is capable of detecting a phase error and a frequency error of an input signal based on a pattern, such as a sync pattern, having a predetermined uniform distribution over an entire range. The phase locked loop circuit includes a sampler which samples an input signal according to a sampling clock output from the phase locked loop circuit; a pattern detection signal/phase error generation unit which generates a pattern detection signal indicating the detection of a predetermined pattern, detects a phase error between the sampled input signal and a zero crossing point of the input signal if the sampled input signal output from the sampler has the predetermined pattern, and outputs the detected phase error, and a sampling clock generation unit which generates the sampling clock based on the pattern detection signal and the phase error, wherein the predetermined pattern is a pattern which is uniformly distributed over the entire range where the input signal can be inputted.

### CROSS-REFERENCE TO RELATED APPLICATIONS

This application claims the benefit of Korean Patent Application No. 2005-73448, filed on Aug. 29, 2005, in the Korean Intellectual Property Office, the disclosure of which is incorporated herein in its entirety by reference.

### BACKGROUND OF THE INVENTION

1. Field of the Invention

Aspects of the present invention relate to a phase locked loop (PLL) circuit and a phase locked loop control method, and more particularly, to a phase locked loop circuit and a phase locked loop control method suitable for a high density optical disc reproducing system.

2. Description of the Related Art

Optical disc reproducing systems reproduce data recorded on optical discs such as compact discs (CDs), digital versatile discs (DVDs), blue-ray discs (BDs), and high definition (HD) DVDs. Optical disc reproducing systems for BD and HD-DVD systems are referred to as high density optical disc reproducing systems.

Optical disc reproducing systems require a sampling clock (or a bit clock) synchronized with a radio frequency (RF) signal in order to reproduce the RF signal which is read from an optical disc. The sampling clock is generated by a PLL circuit synchronized with the RF signal.

FIG. 1 is a functional block diagram of a representative conventional PLL circuit. Referring to FIG. 1, if an RF signal read from an optical disc is inputted, an analog/digital converter (ADC) 101 samples the RF signal according to the sampling clock output from the PLL circuit. A phase error detector 102 calculates and outputs a phase error between a zero crossing point of the RF signal and the sampled RF signal of the ADC 101. An LPF 103 low-pass-filters the phase error and outputs a low frequency component of the phase error. A digital/analog converter (DAC) 104 converts the low frequency component into an analog signal. A voltage controlled oscillator (VCO) 105 is driven by the output of the DAC 104 to generate a sampling clock. The sampling clock drives the ADC 101, so that the PLL circuit of FIG. 1 forms a closed loop.

However, since the PLL circuit shown in FIG. 1 does not take into consideration a frequency error between the sampled RF signal and the sampling clock, the PLL circuit cannot quickly complete frequency pulling-in processing. Therefore, in order to quickly process frequency pulling-in while also preventing phase locking of the sampling clock, a PLL circuit having a frequency pulling-in function has already been designed.

The PLL circuit having the frequency pulling-in function shown in FIG. 2 begins performing the frequency pulling-in process by using a frequency error detector 202. Specifically, the frequency error detector 202 detects a sync pattern having the maximum run-length shown in FIG. 3 from an RF signal which has been sampled by an ADC 201. Next, the frequency error detector 202 counts the number of sampling clock cycles in a range of the detected sync pattern and outputs the difference between the count value and a predetermined value as a frequency error.

After the frequency error is outputted, the PLL circuit shown in FIG. 2 is switched into a phase locking mode so that the PLL circuit shown in FIG. 2 operates in a similar fashion to the PLL circuit shown in FIG. 1.

The phase error detectors 102 and 203 shown in FIGS. 1 and 2 detect an amplitude value I(ai) just before the zero crossing point and an amplitude value I(bi) just after the zero crossing point with reference to the zero crossing point from the RF signal sampled according to the sampling clock, and perform calculations on the detected amplitude values using Equation 1 below to obtain a phase error PE(i) between the zero crossing point and the sampled RF signal.
phase error (PE(i))=|I(bi)|−|I(ai)| [Equation 1]

For example, when the sampling point of the RF signal sampled according to the sampling clock is given as shown in FIG. 4, since the amplitude value I(bi) just after the zero crossing point is equal to the amplitude value I(ai) just before the zero crossing point, the phase error calculated using Equation 1 is 0.

When the sampling point of the RF signal sampled according to the sampling clock is given as shown in FIG. 5, since the amplitude value I(bi) just after the zero crossing point is smaller than the amplitude value I(ai) just before the zero crossing point, the phase error calculated using Equation 1 has a negative value.

When the sampling point of the RF signal sampled according to the sampling clock is given as shown in FIG. 6, since the amplitude value I(bi) just after the zero crossing point is larger than the amplitude value I(ai) just before the zero crossing point, the phase error calculated using Equation 1 has a positive value.

In this way, the PLL circuits use the zero crossing point as an indicator of the phase of the RF signal, and detect the phase error between the sampled RF signal and the zero crossing point based on the amplitude of the sampling point adjacent to the zero crossing point.

However, a high inter-symbol Interference (ISI) may prevent the PLL circuits from detecting the zero crossing point. The high ISI means that the waveform of the RF signal is greatly affected by the ISI. As a spot size of an optical beam becomes larger than a pit length, the ISI affects the waveform of the reproduced RF signal more severely.

The high ISI condition usually occurs in high density optical disc reproducing systems for BD or the like. If the zero crossing point of the RF signal is not detected due to the high ISI, the phase locking of the RF signal may fail, and as a result, data cannot be reproduced in a stable fashion by the optical disc reproducing system.

### SUMMARY OF THE INVENTION

An aspect of the present invention provides a phase locked loop circuit and a phase locked loop control method suitable for an optical disc reproducing system having a high ISI condition.

Another aspect of the present invention also provides a phase locked loop circuit and a phase locked loop control method suitable for a high density optical disc reproducing system.

Another aspect of the present invention also provides a phase locked loop circuit and a phase locked loop control method capable of detecting a phase error and a frequency error of an input signal based on a pattern such as a sync pattern having a predetermined uniform distribution over an entire range.

According to an aspect of the present invention, there is provided a phase locked loop circuit including a sampler which samples an input signal according to a sampling clock outputted from the phase locked loop circuit, a pattern detection signal/phase error generation unit which generates a pattern detection signal which indicates the detection of a predetermined pattern and detects and outputs a phase error between the sampled input signal and a zero crossing point of the input signal, if the sampled input signal output from the sampler has the predetermined pattern, and a sampling clock generation unit which generates the sampling clock based on the pattern detection signal and the phase error, wherein the predetermined pattern is a pattern which is uniformly distributed over the entire range where the input signal can be input.

According to another aspect of the present invention, there is provided a phase locked loop circuit including an analog/digital converter which outputs an RF signal input according to a sampling clock outputted from the phase locked loop circuit, a sync pattern detection signal/phase error generation unit which generates a sync pattern detection signal which indicates the detection of the sync pattern and detects a phase error between the sampled RF signal and a zero crossing point of the input RF signal if the sampled RF signal output from the analog/digital converter is a sync pattern, a low pass filter which detects a low frequency component of the phase error in synchronization with the sync pattern detection signal, a frequency error detector which outputs the difference between the sampling clock count value during a period of the sync pattern detection signal and a predetermined number as a frequency error between the frequency of the RF signal and the frequency of a sampling clock, and a sampling clock generation unit which generates the sampling clock using the result of adding the low frequency component of the phase error and the frequency error.

According to another aspect of the present invention, there is provided a phase locked loop circuit including an analog/digital converter which outputs an RF signal input according to a sampling clock outputted from the phase locked loop circuit, a sync pattern detection signal/phase error generation unit which generates a sync pattern detection signal which indicates the detection of the sync pattern and detects a phase error between the sampled RF signal and a zero crossing point of the inputted RF signal if the sampled RF signal output from the analog/digital converter is a sync pattern, a low pass filter which detects a low frequency component of the phase error in synchronization with the sync pattern detection signal, a frequency error detector which outputs the difference between the sampling clock count value (during a period of the sync pattern detection signal) and a predetermined number as a frequency error between the frequency of the RF signal and the frequency of a sampling clock, a sampling clock generation unit which generates the sampling clock by using a result of adding the low frequency component of the phase error and the frequency error, and a mode control unit which controls the operation of the low pass filter and also determines whether or not to transmit the frequency error, so that the phase locked loop circuit is operated in either a frequency pulling-in processing mode or a phase locking processing mode according to the frequency error.

According to another aspect of the present invention, there is provided a phase locked loop circuit in an optical disc reproducing system, including an analog/digital converter which samples an RF signal read from a disc loaded in the optical disc reproducing system according to a sampling clock outputted from the phase locked loop circuit, a sync pattern detection signal/phase error generation unit which generates a sync pattern detection signal that indicates the detection of a sync pattern if the sync pattern is detected within the sampled RF signal outputted from the analog/digital converter, and detects and outputs a phase error between the sampled RF signal and a zero crossing point of the RF signal based on the sampled RF signal, and a sampling clock generation unit which generates the sampling clock based on the sync pattern detection signal and the phase error.

According to another aspect of the present invention, there is provided a phase locked loop control method including the steps of sampling an input signal according to a sampling clock outputted by the phase locked loop, generating a pattern detection signal which indicates the detection of a predetermined pattern and detects and outputs a phase error between the sampled input signal and a zero crossing point of the input signal if the sampled input signal has the predetermined pattern, and generating the sampling clock based on the pattern detection signal and the phase error, wherein the predetermined pattern is a pattern which is uniformly distributed over the entire range where the input signal can be inputted into.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram showing the construction of a conventional PLL circuit;

FIG. 2 is a block diagram showing the construction of a conventional PLL circuit having a frequency pulling-in function;

FIG. 3 shows an example of a maximum run-length detected by a frequency error detector shown in FIG. 2;

FIG. 4 shows an example which illustrates phase error detection using the phase error detectors shown in FIGS. 1 and 2 where the phase error calculation is zero according to equation 1;

FIG. 5 shows an example which illustrates phase error detection using the phase error detectors shown in FIGS. 1 and 2 where the phase error calculation is positive according to equation 1;

FIG. 6 shows an example which illustrates phase error detection using the phase error detectors shown in FIGS. 1 and 2 where the phase error calculation is negative according to equation 1;

FIG. 7 is a block diagram showing the construction of a phase locked loop circuit according to an embodiment of the present invention;

FIG. 8 is a detailed block diagram showing the construction of the pattern detection signal/phase error generation unit shown in FIG. 7;

FIG. 9 shows an example of a sync pattern of an RF signal reproduced by a high density optical disc reproducing system according to an aspect of the present invention;

FIG. 10 is a block diagram showing the construction of a phase locked loop circuit according to another embodiment of the present invention;

FIG. 11 is a detailed circuit diagram of the frequency error detector shown in FIG. 10;

FIG. 12 is a block diagram showing the construction of a phase locked loop circuit according to still another embodiment of the present invention;

FIG. 13 is a detailed block diagram showing the construction of the sync pattern detection signal/phase error generation unit shown in FIG. 12;

FIG. 14 is a detailed circuit diagram of the frequency error detector shown in FIG. 12;

FIG. 15 is a block diagram showing the construction of a phase locked loop circuit according to another embodiment of the present invention;

FIG. 16 is a flowchart showing the operation of a phase locked loop control method according to another embodiment of the present invention;

FIG. 17 is a detailed flowchart of a pattern detection signal/phase error generation step shown in FIG. 16; and

FIG. 18 is a flowchart showing the operation of a phase locked loop control method according to another embodiment of the present invention.

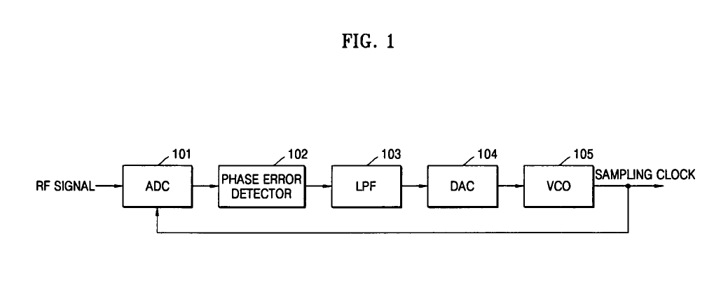

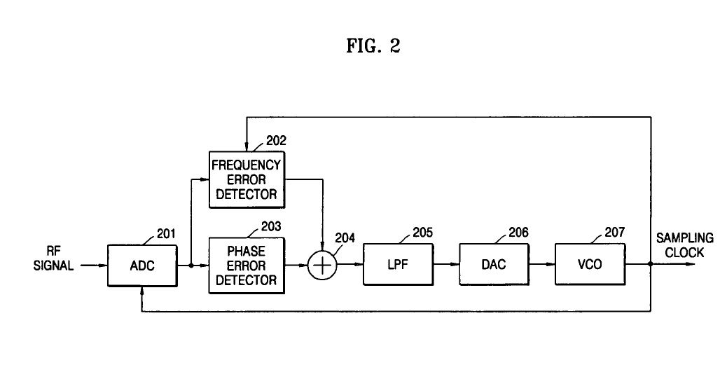

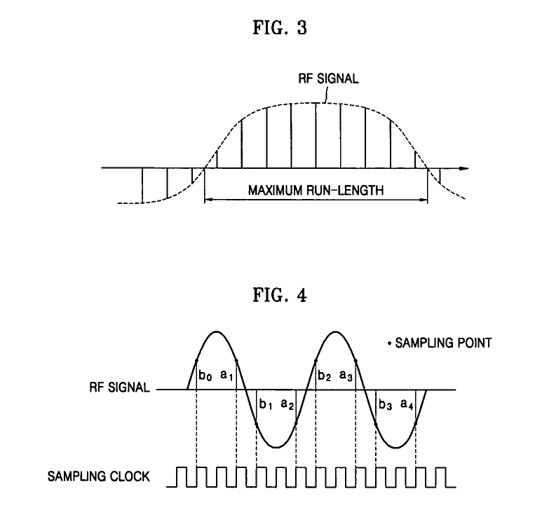

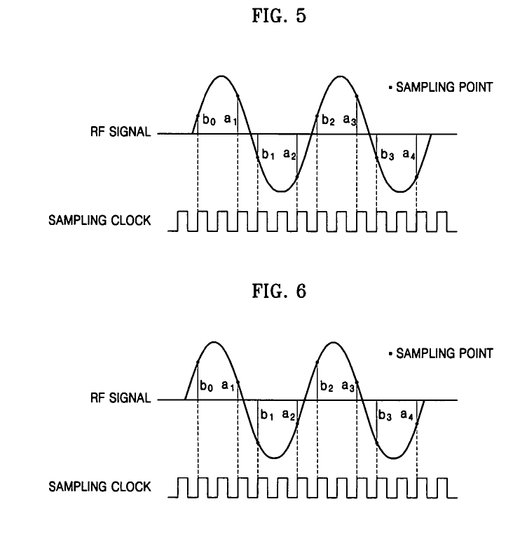

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

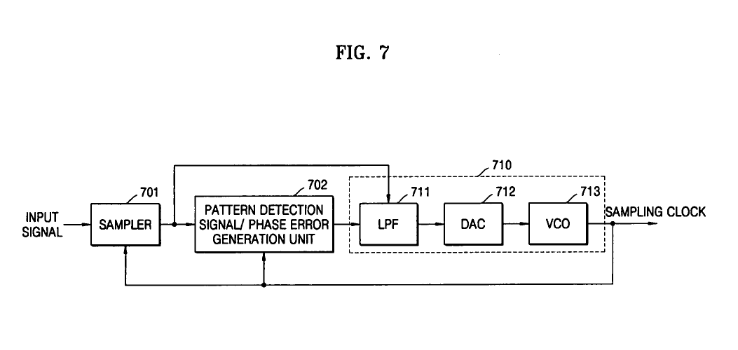

FIG. 7 is a functional block diagram of a phase locked loop circuit according to an embodiment of the present invention. Referring to FIG. 7, the phase locked loop circuit includes a sampler 701, a pattern detection signal/phase error generation unit 702, and a sampling clock generation unit 710.

The sampler 701 samples an input signal according to a sampling clock outputted from a phase locked loop circuit. The input signal may have the shape of a sinusoidal wave, and the sampler 701 may sample and output the amplitude of the input signal at a rising edge of the sampling clock.

If the sampled input signal outputted from the sampler 701 has a predetermined pattern, the pattern detection signal/phase error generation unit 702 generates a pattern detection signal indicating the detection of a predetermined pattern and detects and generates a phase error between the sampled input signal and a zero crossing point of the input signal based on the sampled input signal.

The predetermined pattern is uniformly distributed over the entire range where the input signal can be inputted, and for example, a sync pattern may be used as the predetermined pattern. Since the sync pattern is longer than a laser spot, the ISI in the sync pattern can be counteracted at the zero crossing point. Therefore, even in a high ISI condition, a sync pattern phase can be accurately detected without influence by the ISI.

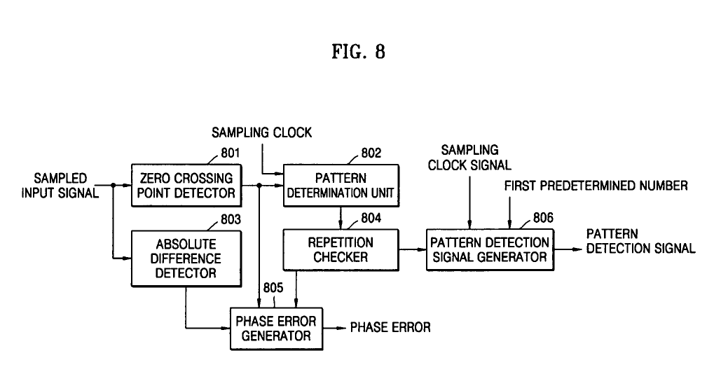

The pattern detection signal/phase error generation unit 702 may be constructed as shown in FIG. 8. FIG. 8 is a detailed block diagram showing the construction of the pattern detection signal/phase error generation unit 702 shown in FIG. 7.

Referring to FIG. 8, the pattern detection signal/phase error generation unit 702 includes a zero crossing point detector 801, a pattern determination unit 802, an absolute difference detector 803, a repetition checker 804, a phase error generator 805, and a pattern detection signal generator 806.

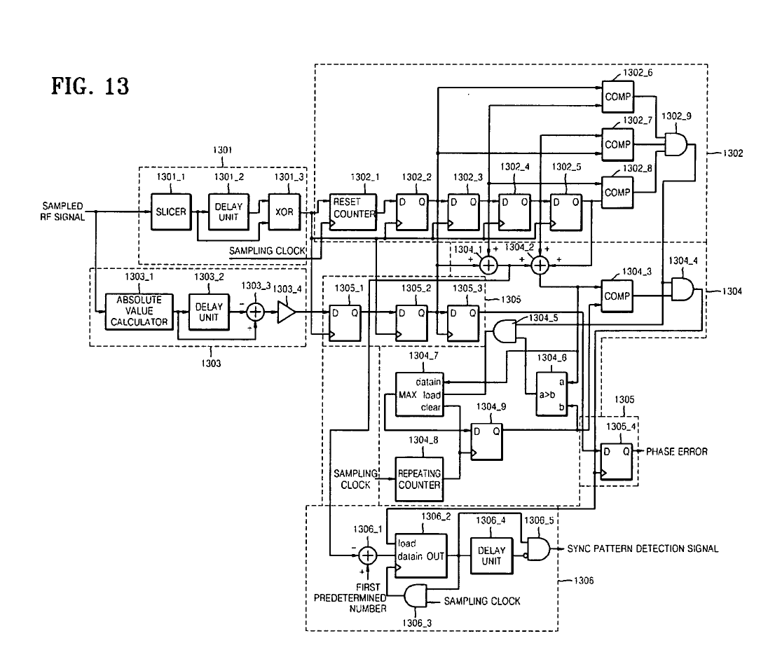

The zero crossing point detector 801 detects a zero crossing point from the sampled input signal. The zero crossing point detector 801 may be constructed like a zero crossing point detector 1301 described later with reference to FIG. 13.

The pattern determination unit 802 is reset according to the zero crossing point detected by the zero crossing point detector 801, and determines whether or not the sampled input signal has a predetermined pattern by using a sampling clock count value. The sampling clock count value is latched at each zero crossing point and, by comparing similarities of the latched values, it can be determined whether or not the sampled input signal has the predetermined pattern. If the latched values are similar to each other, it is determined that the sampled input signal has the predetermined pattern.

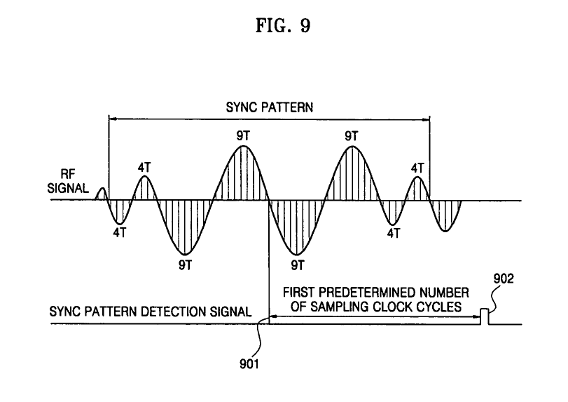

For example, if the predetermined pattern is the sync pattern shown in FIG. 9, the pattern determination unit 802 is reset according to the zero crossing point, and a plurality of sampling clock count values are latched. If, based on the plurality of latched values, the pattern determination unit 802 recognizes that two 4T run-lengths, four 9T run-lengths, and two 4T run-lengths are sequentially input, or, if based on the plurality of latched values, the pattern determination unit 802 recognizes that at least four 9T run-lengths are sequentially inputted, the pattern determination unit 802 outputs a signal indicating that the input signal has a predetermined pattern. The pattern determination unit 802 may have the same construction as a pattern determination unit 1302 described later with reference to FIG. 13.

The absolute difference detector 803 detects the absolute difference between the sampled input signals. The absolute difference detector 803 may have the same construction as an absolute difference detector 1303 described later with reference to FIG. 13.

The repetition checker 804 checks to see if the determination of whether or not the sampled input signal has the predetermined pattern has been repeatedly performed. The repetition checker 804 makes this determination based on the signal output from the pattern determination unit 802 and the values latched in the pattern determination unit 802. Specifically, the repetition checker 804 confirms that the determination has been repeatedly performed if the repetition checker 804 detects that the signal indicating that the sampled input signal is determined to be the predetermined pattern is transmitted twice and if the value latched in the pattern determination unit 802 is maintained at a maximum value. If the repetition checker 804 confirms that the determination has been repeatedly performed, the repetition checker 804 outputs a signal indicating that the determination that the sampled input signal has the predetermined pattern is repeatedly performed. If the repetition checker 804 may have the same construction as a repetition checker 1304 described later with reference to FIG. 13.

If the signal indicating that the determination that the sampled input signal has the predetermined pattern is repeatedly performed is outputted from the repetition checker 804, the phase error generator 805 generates the absolute difference between the two sampled input ports detected by the absolute difference detector 803 as a phase error. This phase error is an error between the sampled input signal and the zero crossing point in synchronization with the zero crossing point detected by the zero crossing point detector 801. The phase error generator 805 may have the same construction as a phase error generator 1305 described later with reference to FIG. 13.

If the signal indicating that the determination that the sampled input signal has the predetermined pattern is repeatedly performed is outputted from the repetition checker 804, the pattern detection signal generator 806 generates a pattern detection signal at a time point. This time point is delayed by a first predetermined number of sampling clock cycles from the zero crossing point located at the center of the predetermined pattern.

Referring to FIG. 9, a time point 901 is the zero crossing point located at the center of the predetermined pattern. Therefore, if the signal indicating the determination that the sampled input signal has the predetermined pattern has been repeatedly performed is outputted from the repetition checker 804, the pattern detection signal generator 806 counts the sampling clock cycles inputted from the time point 901. If the count value approaches the first predetermined number, the pattern detection signal generator 806 determines a time point 902 when the first predetermined number of sampling clock cycles elapses, and generates the pattern detection signal. The first predetermined number is constant. The pattern detection signal generator 806 may have the same construction as a pattern detection signal generator 1306 described later with reference to FIG. 13.

The sampling clock generation unit 710 of FIG. 7 generates the sampling clock based on the pattern detection signal and the phase error output from the pattern detection signal/phase error generation unit 702. As shown in FIG. 7, the sampling clock generation unit 710 includes a low pass filter (LPF) 711, a digital/analog converter (DAC) 712, and a voltage controlled oscillator (VCO) 713.

The LPF 711 low-pass-filters the phase error and outputs a low frequency component of the phase error in synchronization with the pattern detection signal. The DAC 712 converts the low frequency component of the phase error into an analog signal. The VCO 713 is driven by the output of the DAC 712 to generate the sampling clock. The sampling clock is transmitted to the sampler 701 and the pattern detection signal/phase error generation unit 702.

When the phase locked loop circuit of FIG. 7 is employed in an optical disc reproducing system, the input signal may be defined as an RF signal read from a disc loaded into the optical disc reproducing system, the sampler 701 may be defined as an analog/digital converter, and the predetermined pattern may be defined as a sync pattern. However, the input signal, sampler, and the predetermined pattern are not limited to these examples.

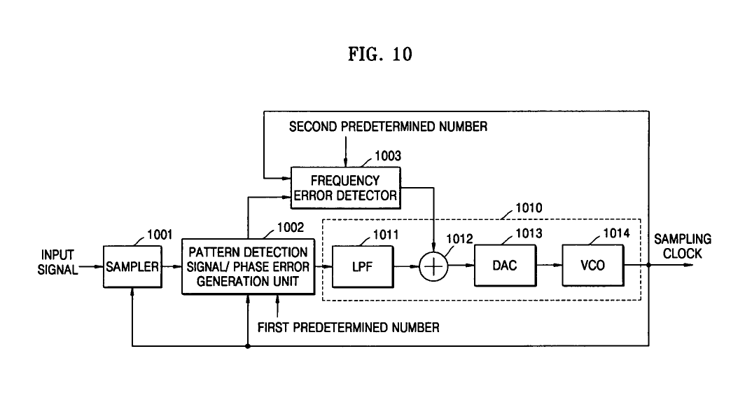

FIG. 10 is a functional block diagram of a phase locked loop circuit according to another embodiment of the present invention. Referring to FIG. 10, the phase locked loop circuit includes a sampler 1001, a pattern detection signal/phase error generation unit 1002, a frequency error detector 1003, and a sampling clock generation unit 1010.

The embodiment illustrated in FIG. 10 is the same as the embodiment illustrated in FIG. 7 except that the frequency error detector 1003 and an adder 1012 of the sampling clock generation unit 1010 are included in the embodiment illustrated in FIG. 10. To avoid redundancy, the description of the embodiment will focus on the frequency error detector 1003 and the components which have been added or changed in the sampling clock generation unit 1010.

The frequency error detector 1003 detects the difference between a second predetermined number and the sampling clock count value during the period of the pattern detection signal transmitted from the pattern detection signal/phase error generation unit 1002, and outputs the difference as a frequency error between the frequency of the input signal and the frequency of the sampling clock.

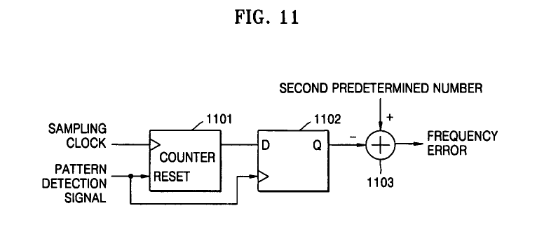

The frequency error detector 1003 may preferably be constructed as shown in FIG. 11, although there may be numerous other ways to construct it in accordance with the present invention. FIG. 11 is a detailed view of the frequency error detector 1003. Referring to FIG. 11, the frequency error detector 1003 includes a counter 1101, a D flip-flop 1102, and a subtractor 1103.

The counter 1101 is reset by the pattern detection signal, and counts the sampling clock. The counter 1101 may be an up counter. The count value of the counter 1101 is transmitted to the D flip-flop 1102. The D flip-flop 1102 stores the count value transmitted from the counter 1101 and outputs the stored count value in synchronization with the pattern detection signal. Therefore, a signal outputted from the D flip-flop 1102 is the sampling clock count value during the period of the pattern detection signal.

The subtractor 1103 detects the difference between the count value transmitted from the D flip-flop 1102 and the second predetermined number, and after detecting the difference, the subtractor outputs the difference. The difference outputted from the subtractor 1103 is a frequency error between the frequency of the input signal and the frequency of the sampling clock. The second predetermined number is the number of sampling clock cycles generated during the period of the predetermined pattern, and has a fixed value.

The frequency error outputted from the frequency error detector 1003 is transmitted to the sampling clock generation unit 1010.

The sampling clock generation unit 1010 includes an LPF 1011, an adder 1012, a DAC 1013, and a VCO 1014. The LPF 1011, the DAC 1013, and the VCO 1014 are the same as the LPF 711, the DAC 712, and the VCO 713 shown in FIG. 7. The adder 1012 adds a low frequency component of the phase error output from the LPF 1011 and the frequency error output from the frequency error detector 1003, and then transmits the added result to the DAC 1013.

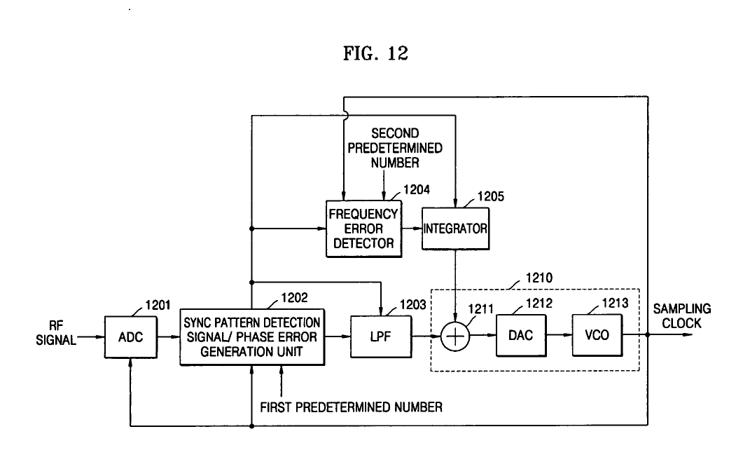

FIG. 12 is a functional block diagram of a phase locked loop circuit according to still another embodiment of the present invention. FIG. 12 shows a phase locked loop circuit which can be employed in an RF signal reproducing system such as an optical disc reproducing system.

Referring to FIG. 12, the phase locked loop circuit includes an analog/digital converter (ADC) 1201, a sync pattern detection signal/phase error generation unit 1202, an LPF 1203, a frequency error detector 1204, an integrator 1205, and a sampling clock generation unit 1210.

The ADC 1201 samples the input RF signal according to a sampling clock output from the phase locked loop circuit of FIG. 12 and outputs the sampled RF signal. The inputted RF signal may preferably be an analog RF signal generated in a non-return-to-zero inverter (NRZI) channel bit sequence, although other types of signals may also be used. The analog RF signal is constructed of a plurality of synchronization blocks, each block being of equal length and each block having sync patterns in the corresponding heads thereof.

If the sampled RF signal outputted from the ADC 1201 has the sync pattern, the sync pattern detection signal/phase error generation unit 1202 generates a sync pattern detection signal which indicates the detection of the sync pattern, and then detects and outputs a phase error between the sampled RF signal and a zero crossing point of the input RF signal. The generated sync pattern detection signal may preferably be defined as an aligned sync signal, and the phase error may preferably be defined as a nominal phase error, although both the generated sync pattern detection signal and phase error may be defined in other ways in accordance with the present invention.

The sync pattern detection signal/phase error generation unit 1202 may be constructed as shown in FIG. 13. FIG. 13 is a detailed circuit diagram of the sync pattern detection signal/phase error generation unit 1202. The sync pattern detection signal/phase error generation unit 1202 includes a zero crossing point detector 1301, a pattern determination unit 1302, an absolute difference detector 1303, a repetition checker 1304, a phase error generator 1305, and a pattern detection signal generator 1306.

The zero crossing point detector 1301 detects the zero crossing point from the sampled RF signal. The zero crossing point detector 1301 includes a slicer 1301_1, a delay unit 1301_2, and an exclusive OR (also known as an “XOR”) gate 1301_3.

The slicer 1301_1 outputs 1 if the input sampled RF signal is equal to or greater than a zero line, and 0 if the input sampled RF signal is less than the zero line. The sampled RF signal is a digitalized RF signal.

The delay unit 1301_2 delays an output of the slicer 1301_1 for one sampling clock cycle.

The exclusive OR gate 1301_3 outputs the exclusive OR of the output of the slicer 1301_1 and the output of the delay unit 1301_2. Therefore, the zero crossing point of the input sampled RF signal is detected. The output of the exclusive OR gate 1301_3 resets a counter 1302_1 in the pattern determination unit 1302 to 1, used to trigger four D flip-flops 1302_2, -1302_5 and four D flip-flops 1305_11305_4 in the phase error generator 1305.

The pattern determination unit 1302 is reset according to the zero crossing point detected by the zero crossing point detector 1301, and determines whether or not the input sampled RF signal has a sync pattern.

The pattern determination unit 1302 includes a counter 1302_1, four D flip-flops 1302_2-1302_5, three comparators 1302_6-1302_8, and an AND gate 1302_9.

The counter 1302_1 is an up counter and is set to 1 to count the sampling clock cycles when the zero crossing point is detected. The count value of the counter 1302_1 is transmitted to the D flip-flop 1302_2, which is connected to the next stage.

In the four D flip-flops 1302_2-1302_5, an input port of the first D flip-flop 1302_2 is connected to an output port of the counter 1302_1, an input port of the second D flip-flop 1302_3 is connected to an output port of the first D flip-flop 1302_2, an input port of the third D flip-flop 1302_4 is connected to an output port of the second D flip-flop 1302_2, and an input port of the fourth D flip-flop 1302_5 is connected to an output port of the third D flip-flop 1302_4, so that the four run-lengths detected at the zero crossing point are sequentially latched.

Specifically, the four D flip-flops 1302_2-1302_5 are triggered at the rising edge of the output of the exclusive OR gate 1301_3. This means that every time that the zero crossing point is detected, the values latched in the four D flip-flops 1302_2-1302_5 change. When the inputted RF signal has the sync pattern, the values latched in the four D flip-flops 1302_2˜1302_5 are similar to each other, and the sum of the four latched values is a maximum value. The reason that the sum of these four latched values is a maximum value is because the run-length included in the sync pattern is the longest run-length among the channel bits. For example, if the inputted RF signal has the sync pattern shown in FIG. 9, each of the four D flip-flops 1302_2 1 1302_5 can latch 9T run-lengths.

The three comparators 1302_6 1 1302_8 are used to determine the similarity of the values latched in the four D flip-flops 1302_2 1 1302_5. If the condition of Equation 2, that the absolute value of the difference between two input signals is smaller than the value obtained by multiplying one input signal by a predetermined ratio, is satisfied, the three comparators 1302_6 1 1302_8 determine that the two compared values are similar to each other.
|Input 1−Input 2|<Input 2×α [Equation 2]

In Equation 2, α is smaller than 1, so that if the ISI in a channel is low, a is set to a small value (for example, ⅛) so that the three comparators 1302_6-1302_8 can accurately detect the sync pattern, and if the ISI in the channel is high, α is set to a large value (for example, ¼) in order to ensure that the three comparators 1302_6-1302_8 to detect the sync pattern.

If t Equation 2 is satisfied, the three comparators 1302_6-1302_8 output 1, and if not, the three comparators 1302_6-1302_8 output 0. The comparator 1302_6 compares the value latched in the first D flip-flop 1302_2 with the value latched in the second D flip-flop 1302_3. The comparator 1302_7 compares the value latched in the second D flip-flop 1302_3 with the value latched in the third D flip-flop 1302_4. The comparator 1302_8 compares the value latched in the third D flip-flop 1302_4 with the value latched in the fourth D flip-flop 1302_5. In this way, the three comparators 1302_6-1302_8 compare each of the three values latched in each of the corresponding three D flip-flops 1302_2-1302_4 against each of the other values.

The AND gate 1302_9 performs an AND operation on the outputs of the three comparators 1302_6-1302_8 to determine the similarity of the values latched in the four D flip-flops 1302_2-1302_5. If the output of the AND gate 1302_9 is at a high level, the values latched in the four D flip-flops 1302_2-1302_5 are similar to each other, so that a signal is outputted indicating that the currently inputted sampled RF signal has the sync pattern. In other cases, the output of the AND gate 1302_9 is at a low level, and a signal is outputted indicating that the inputted sampled RF signal does not have the sync pattern.

The absolute difference detector 1303 detects the absolute value of the difference between the sampled RF signals. The absolute difference detector 1303 includes an absolute value calculator 1303_1, a delay unit 1303_2, a subtractor 1303_3, and an amplifier 1303_4.

The absolute value calculator 1303_1 calculates the absolute value of the inputted sampled RF signals. The delay unit 1303_2 delays the output of the absolute value calculator 1303_1 for one sampling clock cycle.

The subtractor 1303_3 subtracts the output of the delay unit 1303_2 from the output of the absolute value calculator 1303_1. The amplifier 1303_4 amplifies the output of the subtractor 1303_3 using a predetermined index. The output of the amplifier 1303_4 is a phase error between adjacent sampled RF signals.

The repetition checker 1304 checks whether or not the sync pattern determination unit 1302 has repeatedly determined whether the sampled RF signal has the sync pattern. Specifically, the repetition checker 1304 checks whether or not the sync pattern determination unit 1302 has twice determined that the sampled RF signal has the sync pattern, based on the result of the determination of the similarity of a plurality of run-lengths latched in the sync pattern determination unit 1302 and the sum of the plurality of run-lengths latched therein.

The repetition checker 1304 includes two adders 1304_1 and 1304_2, two comparators 1304_3 and 1304_6, two AND gates 1304_4 and 1304_5, a maximum-value register 1304_7, a repeating counter 1304_8, and a D flip-flop 1304_9.

The adder 1304_1 adds the value latched in the first D flip-flop 1302_2 and the value latched in the second D flip-flop 1302_3 included in the sync pattern determination unit 1302. The adder 1304_2 adds the added value of the adder 1304_1 to the value latched in the third D flip-flop 1302_4 and the value latched in the fourth D flip-flop 1302_5 included in the sync pattern determination unit 1302. Therefore, if the currently inputted sampled RF signal has the sync pattern, the value outputted from the adder 1304_2 is a maximum value, and the value outputted from the adder 1304_1 is the value of the time point 901 of the zero crossing point located at the center of the sync pattern of FIG. 9.

The comparator 1304_3 compares the output of the adder 1304_2 with the previous maximum value latched in the D flip-flop 1304_9 to determine whether or not the value outputted from the adder 1304_2 is equal to the value latched in the D flip-flop 1304_9. If the value outputted from the adder 1304_2 is equal to the value latched in the D flip-flop 1304_9, a signal indicating that the sync pattern is repeatedly detected is outputted. Accordingly, the AND gate 1304_4 outputs 1 to indicate that the value outputted from the adder 1304_2 is equal to the maximum value latched in the D flip-flop 1304_9.

In order to check the repetition of the adder 1304_2, the comparators 1304_6, and the AND gate 1304_5, the maximum value register 1304_7 serves as a maximum value register for storing the maximum value of the sum of the values outputted from the four D flip-flops 1302_2 1302_5 included in the sync pattern determination unit 1302.

The repeating counter 1304_8 serves as a sampling clock frequency divider for updating the maximum value register 1304_7 and the D flip-flop 1304_9. The maximum value latched in the D flip-flop 1304_9 may be compared with the output of the adder 1304_2.

If the repetition checker 1304 repeatedly determines whether the sampled RF signal has the sync pattern, the phase error generator 1305 outputs the absolute difference between the two sampled RF signals detected by the absolute difference detector 1303 as the phase error between the sampled RF signal and the zero crossing point, in synchronization with the zero crossing point.

The phase error generator 1305 is constructed of four D flip-flops 1305_1-1305_4. When the output of the XOR 1301_3, which is included in the zero crossing point detector 1301, is at a rising edge, the three D flip-flops 1305_1-1305_3 are triggered to sequentially latch the absolute difference detected by the absolute difference detector 1303.

Therefore, when the four 9T run-lengths corresponding to the sync pattern of FIG. 9 are latched in the D flip-flops 1302_2-1302_5 included in the sync pattern determination unit 1302, the value latched in the D flip-flop 1305_3 becomes the phase error at the central zero crossing point of the sync pattern of FIG. 9. The D flip-flop 1305_4 latches the absolute value transmitted from the D flip-flop 1305_3 and, in synchronization with the output of the AND gate 1304_3 in the repetition checker 1304, outputs the latched absolute difference as the phase error. The phase error outputted from the D flip-flop 1305_4 is the phase error between the inputted sampled RF signal and the zero crossing point of the inputted RF signal.

If the determination is repeatedly performed by the repetition checker 1304, the sync pattern detection signal generation unit 1306 generates a pattern detection signal at a time point delayed by a first predetermined number of sampling clock cycles from the zero crossing point. The zero crossing point is located at the center of the sync pattern. Therefore, a subtractor 1306_1, a down counter 1306_2, an AND gate 1306_3, a delay unit 1306_4, and an AND gate 1306_5 included in the sync pattern detection signal generation unit 1306 have a delay mechanism.

The subtractor 1306_1 subtracts the first predetermined number from the output of the adder 1304_1, which is included in the repetition checker 1304. The first predetermined number is constant and corresponds to the first predetermined number of sampling clock cycles defined in FIG. 9.

The down counter 1306_2 loads the output of the subtractor 1306_1 according to the output of the AND gate 1304_3 of the repetition checker 1304 and, in synchronization with the output of the AND gate 1306_3, counts down. The AND gate 1306_3 performs an AND operation on the output of the down counter 1306_2 and the sampling clock. Then, the AND gate 1306_3 provides the resultant value of the AND operation to a clock port of the down counter 1306_2. The delay unit 1306_4 delays the down count value of the down counter 1306_2 by one sampling clock cycle. The AND gate 1306_5 performs an AND operation on the output of the down counter 1306_2 and the inverted value of the output of the delay unit 1306_4. Then, the AND gate 1306_5 outputs the resultant value of its AND operation. The output of the AND gate 1306_5 is a sync pattern detection signal.

The numbers of D flip-flops and comparators can vary according to the sync pattern which is to be detected.

The LPF 1203 shown in FIG. 12 low-pass-filters the phase error outputted from the sync pattern detection signal/phase error generation unit 1202 to detect and output a low frequency component of the phase error. The outputted low frequency component should be in synchronization with the sync pattern detection signal outputted from the sync pattern detection signal/phase error generation unit 1202.

The frequency error detector 1204 detects the difference between a second predetermined number and the sampling clock count value during a period of the sync pattern detection signal output from the sync pattern detection signal/phase error generation unit 1202, and outputs the difference as a frequency error between the frequency of the RF signal and the frequency of a sampling clock. The second predetermined number is the number of sampling clock cycles generated during the sync pattern, and has a fixed value.

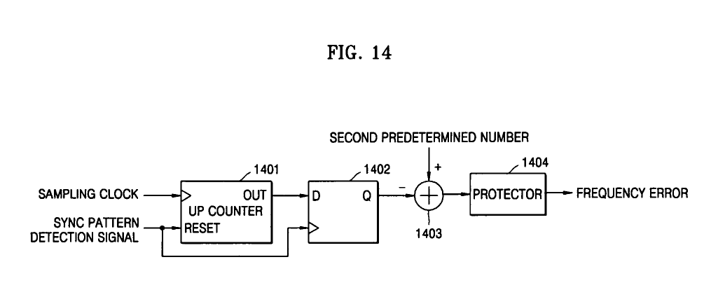

The frequency error detector 1204 may preferably be constructed as shown in FIG. 14. However, there are numerous other ways to construct a frequency error detector in accordance with the present invention. Referring to FIG. 14, the frequency error detector 1204 includes an up counter 1401, a D flip-flop 1402, a subtractor 1403, and a protector 1404.

The up counter 1401 performs up-counting according to the sampling clock and is reset by the input sync pattern detection signal. The count value is stored in the D flip-flop 1402. The up counter 1401, the D flip-flop 1402, and the subtractor 1403 operate in the same fashion as the counter 1101, the D flip-flop 1102, and the subtractor 1103 of FIG. 11 operate.

If the frequency error detected by the subtractor 1403 is within a predetermined range, the protector 1404 outputs the same frequency error detected by the subtractor 1403 as the frequency error output. Otherwise, the frequency error detector outputs “0” in order to protect the phase locked loop circuit from phase locking failure.

The integrator 1205 of FIG. 12 integrates the frequency error outputted from the frequency error detector 1204 and sends the integrated frequency error to the sampling clock generation unit 1210, synchronized with the sync pattern detection signal transmitted from the sync pattern detection signal/phase error generation unit 1202.

The sampling clock generation unit 1210 includes an adder 1211, a DAC 1212, and a VCO 1213. The adder 1211, the DAC 1212, and the VCO 1213 are the same as the adder 1012, the DAC 1013, and the VCO 1014 shown in FIG. 10. The LPF 1203 of FIG. 12 may be included in the sampling clock generation unit 1210 in the same fashion that the LPF 1011 is included in FIG. 10. However, the LPF 1011 of FIG. 10 does not need to be included in the sampling clock generation unit 1210 in the same way that the LPF 1203 is included in FIG. 12. The sampling clock generation unit 1210 generates the sampling clock by using the result of the addition of the low frequency component of the phase error, transmitted from the LPF 1203, and the frequency error, transmitted from the integrator 1205.

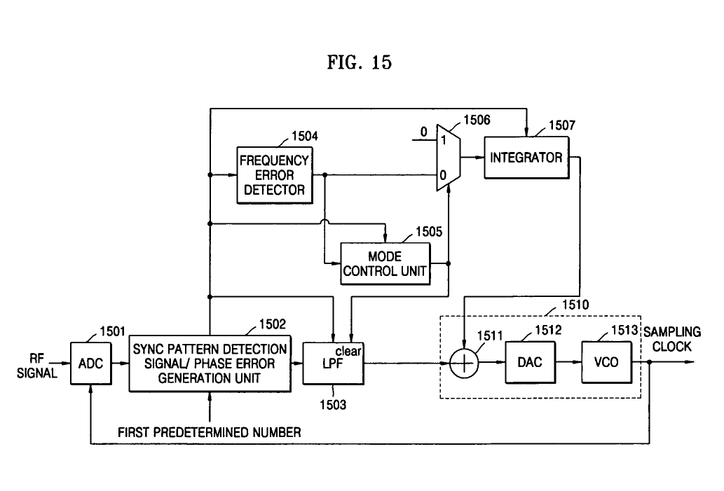

FIG. 15 is a functional block diagram of a phase locked loop circuit according to another embodiment of the present invention. Referring to FIG. 15, the phase locked loop circuit includes an ADC 1501, a sync pattern detection signal/phase error generation unit 1502, a LPF 1503, a frequency error detector 1504, a mode control unit 1505, a multiplexer 1506, an integrator 1507, and a sampling clock generation unit 1510.

The phase locked loop circuit shown in FIG. 15 differs from that of FIG. 12 in that operation modes of the phase locked loop circuit of FIG. 15 are divided into an initial frequency pulling-in processing mode and a subsequent phase locking processing mode. The phase locked loop circuit shown in FIG. 15 switches between the frequency pulling-in processing mode and the phase locking processing mode by using the mode control unit 1505 and the multiplexer 1506.

If the value of the frequency error outputted from the frequency error detector 1504 has a non-zero value, and if the frequency error is synchronized with the sync pattern detection signal outputted from the sync pattern detection signal/phase error generation unit 1502, the mode control unit 1505 clears the LPF 1503, so that the phase locked loop circuit operates in the frequency pulling-in processing mode and the frequency error is transmitted to the sampling clock generation unit 1510 through the integrator 1507.

If the frequency error outputted from the frequency error detector 1504 has a value of zero, the mode control unit 1505 does not clear the LPF 1503. When the mode control unit 1505 does not clear the LPF 1503, it causes the phase locked loop circuit to operate in the phase locking processing mode and output the phase error from the LPF 1503.

Thus, the mode control unit 1505 controls the operation of the LPF 1503 and determines whether or not to transmit the frequency error, so that the phase locked loop circuit shown in FIG. 15 operates in either the frequency pulling-in processing mode or the phase locking processing mode, depending on whether the value of the frequency error is non-zero or zero, respectively.

The sampling clock generation unit 1510 generates the sampling clock by adding the phase error transmitted from the LPF 1503 to the frequency error provided from the integrator 1507.

The mode control unit 1505 may preferably be constructed of switches.

Under the control of the mode control unit 1505, the multiplexer 1506 selects between 0 and the frequency error output from the frequency error detector 1504 and transmits either the value zero, or the value of the frequency error output, to the integrator 1507.

In synchronization with the sync pattern detection signal output from the sync pattern detection signal/phase error generation unit 1502, the integrator 1507 integrates the signal output from the multiplexer 1506 and transmits the integrated signal to the sampling clock generation unit 1510.

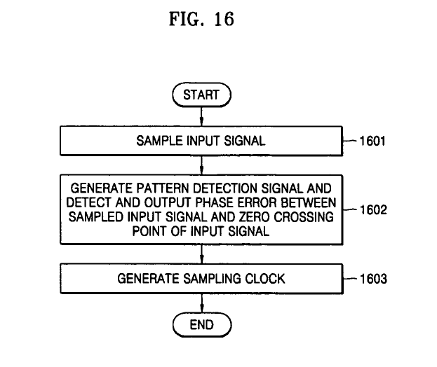

FIG. 16 is a flowchart showing the operation of a phase locked loop control method according to another embodiment of the present invention.

In a system having the phase locked loop control function, an input signal is sampled based on a sampling clock output by the phase locked loop control (1601). The sampling may be performed in the same fashion as the sampling of the sampler 701 of FIG. 7, or the sampling of the ADC 1201 of FIG. 12.

If the sampled input signal has a predetermined pattern, the system generates a pattern detection signal indicating the detection of the predetermined pattern, and detects and outputs a phase error between the sampled input signal and a zero crossing point of the input signal (1602). The predetermined pattern is the same as the predetermined pattern defined in FIG. 7.

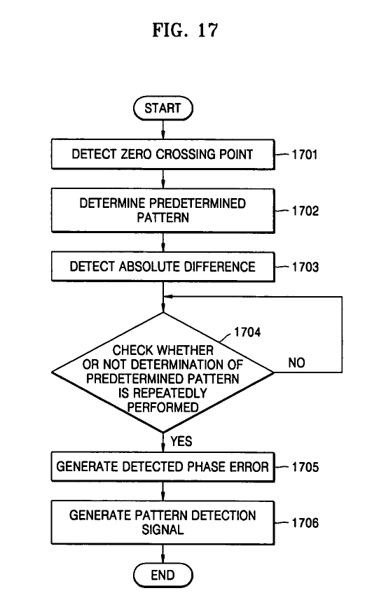

Specifically, the system can generate the pattern detection signal and the phase error as shown in FIG. 17. FIG. 17 is a detailed flowchart of operation 1602 shown in FIG. 16.

Referring to FIG. 17, the system first detects a zero crossing point of a sampled input signal (1701). According to the detected zero crossing point, a sampling clock is counted to determine whether or not the sampled input signal has a predetermined pattern (1702).

After determining whether or not the sampled input signal has a predetermined pattern (1702), the system detects the absolute difference between the sampled input signals (1703). Specifically, the absolute values of the adjacent sampled input signals are obtained, and the difference between the absolute values are obtained.

Next, the system checks whether or not the determination that the sampled input signal has the predetermined pattern is repeatedly performed (1704). If it is found that the system has repeatedly determined that the sampled input signal has the predetermined pattern, the system outputs the absolute difference as a phase error between the sampled input signal and the zero crossing point of the input signal (1705).

Next, the system generates a pattern detection signal at a time point delayed by a first predetermined number of sampling clock cycles from the zero crossing point located at the center of the predetermined pattern (1706). The first predetermined number is the same as the first predetermined number of FIG. 8.

If it is found that the determination that the sampled input signal has the predetermined pattern has not been repeatedly performed, the system is maintained in a standby state (1704).

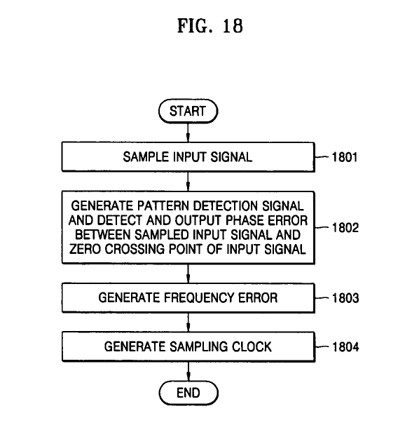

FIG. 18 is a flowchart showing the operation of a phase locked loop control method according to another embodiment of the present invention. FIG. 18 shows a phase locked loop control method further including a frequency error generation operation in the method shown in FIG. 16.

Specifically, as described with reference to FIG. 16, the system performs operations 1801 and 1802 to generate a pattern detection signal and a phase error. Then, the system detects the difference between a sampling clock count value during the period of the pattern detection signal and a second predetermined number as a frequency error between the frequency of an input signal and the frequency of the sampling clock (1803). The second predetermined number has a fixed value like the second predetermined number defined in FIG. 10.

In operation 1804, the system generates the sampling clock by using the result of adding the phase error generated in operation 1802 and the frequency error generated in operation 1803.

A program for executing a phase locked loop control method according to aspects of the present invention can also be embodied as computer readable code on a computer readable recording medium. A computer readable recording medium may beany data storage device that can store data which a computer system can thereafter read. Examples of computer readable recording media include read-only memory (ROM), random-access memory (RAM), CD-ROMs, magnetic tapes, floppy disks, optical data storage devices, and carrier waves (such as data transmission through the internet). Computer readable recording media can also be distributed over network coupled computer systems so that the computer readable code is stored and executed in a distributed fashion.

According to aspects of the present invention, in a high density optical disc reproducing system having a high ISI condition, the phase error and the frequency error of an RF signal are detected based on a predetermined uniformly distributed pattern such as a sync pattern, so that phase locking of the RF signal is quick and reliable even in a high ISI condition. As a result, in the high density optical disc reproducing system having a high ISI condition, it is possible to reliably reproduce data.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A phase locked loop circuit, comprising:
a sampler which samples an input signal according to a sampling clock output;
a pattern detection signal/phase error generation unit which generates a pattern detection signal indicating a detection of a predetermined pattern, detects a phase error between the sampled input signal and a zero crossing point of the input signal if the sampled input signal output from the sampler has the predetermined pattern, and outputs the phase error; and
a sampling clock generation unit which generates the sampling clock based on the pattern detection signal and the phase error.

2. The phase locked loop circuit of claim 1, wherein the pattern detection signal/phase error generation unit comprises:
a zero crossing point detector which detects a zero crossing point of the sampled input signal;
a pattern determination unit which is reset according to the detected zero crossing point and determines whether the sampled input signal has the predetermined pattern by using a sampling clock count value;
an absolute difference detector which detects an absolute difference between the sampled input signals;
a repetition checker which uses an output signal of the pattern determination unit and a count value latched in the pattern determination unit to check whether the pattern determination unit has repeatedly determined that the sampled input signal has the predetermined pattern;
a phase error generator which outputs the absolute difference detected by the absolute difference detector as the phase error between the sampled input signal and the zero crossing point if the repetition checker has determined that the pattern determination unit has repeatedly determined that the sampled input signal has the predetermined pattern, wherein the outputted phase error is outputted in synchronization with the zero crossing point; and
a pattern detection signal generation unit which generates the pattern detection signal if the repetition checker has determined that the pattern determination unit has repeatedly determined that the sampled input signal has the predetermined pattern, wherein the pattern detection signal is generated at a time point which is delayed by a first predetermined number of sampling clock cycles from the zero crossing point located at the center of the predetermined pattern, wherein the first predetermined number is constant.

3. The phase locked loop circuit of claim 2, wherein the predetermined pattern has a sync pattern which is uniformly distributed over the entire range in which the input signal can be inputted.

4. The phase locked loop circuit of claim 2, further comprising:
a frequency error detector which detects a difference between a second predetermined number and the sampling clock count value during a period of the pattern detection signal as a frequency error between a frequency of the input signal and a frequency of the sampling clock;
wherein the sampling clock generation unit further comprises an adder which adds the frequency error and the phase error, and wherein the second predetermined number is a number of sampling clock cycles generated during the period of the predetermined pattern.

5. The phase locked loop circuit of claim 1, wherein the predetermined pattern has a sync pattern.

6. The phase locked loop circuit of claim 1, further comprising:
a frequency error detector which detects the difference between a second predetermined number and a sampling clock count value during a period of the pattern detection signal as a frequency error between a frequency of the input signal and the frequency of the sampling clock; wherein the sampling clock generation unit further comprises an adder which adds the frequency error and the phase error, and wherein the second predetermined number is a number of sampling clock cycles generated during the period of the predetermined pattern.

7. A phase locked loop circuit, comprising:
an analog/digital converter which outputs an RF signal input according to a sampling clock;
a sync pattern detection signal/phase error generation unit which generates a sync pattern detection signal indicating whether a sync pattern has been detected and which detects a phase error between the sampled RF signal and a zero crossing point of the input RF signal if the sampled RF signal output from the analog/digital converter has the sync pattern;
a low pass filter which detects a low frequency component of the phase error in synchronization with the sync pattern detection signal;
a frequency error detector which outputs a difference between a predetermined number and a sampling clock count value during a period of the sync pattern detection signal as a frequency error between a frequency of the RF signal and a frequency of the sampling clock; and
a sampling clock generation unit which generates the sampling clock by using a result of adding the low frequency component of the phase error and the frequency error.

8. The phase locked loop circuit of claim 7, wherein the sync pattern detection signal/phase error generation unit comprises:
a zero crossing point detector which detects a zero crossing point of the sampled RF signal.

9. The phase locked loop circuit of claim 8, wherein the sync pattern detection signal/phase error generation unit further comprises a sync pattern determination unit which is reset according to the zero crossing point detected by the zero crossing point detector and which determines whether the sampled RF signal has the sync pattern by using the sampling clock count value.

10. The phase locked loop circuit of claim 9, wherein the sync pattern detection/ signal phase error generation unit further comprises an absolute difference detector which detects an absolute difference between the sampled RF signals.

11. The phase locked loop circuit of claim 10, wherein the sync pattern detection signal/phase error generation unit further comprises a repetition checker which uses an output signal of the sync pattern determination unit and a count value latched in the pattern determination unit to check whether the pattern determination unit has repeatedly determined that the sampled input signal has the predetermined pattern.;

12. The phase locked loop circuit of claim 11, wherein the sync pattern detection signal phase error generation unit further comprises a phase error generator which outputs the absolute difference detected by the absolute difference detector if the repetition checker has determined that the sync pattern determination unit has repeatedly determined that the sampled input signal has the predetermined pattern, wherein the outputted phase error is outputted in synchronization with the zero crossing point detected by the zero crossing point detector.

13. The phase locked loop circuit of claim 12, wherein the sync pattern detection signal phase error generation unit further comprises a sync pattern detection signal generation unit which generates the sync pattern detection signal if the repetition checker has determined that the pattern determination unit has repeatedly determined that the sampled input signal has the sync pattern, wherein the sync pattern detection signal is generated at a time point which is delayed by a first predetermined number of sampling clock cycles from the zero crossing point located at the center of the sync pattern.

14. The phase locked loop circuit of claim 13, wherein the first predetermined number of sampling clock cycles is constant, the predetermined number in the frequency error detector is a second predetermined number, and the second predetermined number is a number of sampling clock cycles generated during a period of the sync pattern.

15. The phase locked loop circuit of claim 7, further comprising an integrator which integrates the frequency error so that the frequency error is in synchronization with the sync pattern detection signal, and which transmits the integrated frequency error to the sampling clock generation unit.

16. The phase locked loop circuit of claim 7, wherein the frequency error detector further comprises a protector which outputs the detected frequency error as the frequency error when the detected frequency error is within a predetermined range.

17. The phase locked loop circuit of claim 14, further comprising an integrator which integrates the frequency error so that the frequency error is in synchronization with the sync pattern detection signal, and which transmits the integrated frequency error to the sampling clock generation unit.

18. The phase locked loop circuit of claim 14, wherein the frequency error detector further comprises a protector which outputs the detected frequency error as the frequency error when the detected frequency error is within a predetermined range.

19. A phase locked loop circuit, comprising:
an analog/digital converter which outputs an RF signal input according to a sampling clock;
a sync pattern detection signal and phase error generation unit which generates a sync pattern detection signal indicating whether a sync pattern has been detected, and which detects a phase error between the sampled RF signal and a zero crossing point of the input RF signal if the sampled RF signal output from the analog digital converter has the sync pattern;
a low pass filter which detects a low frequency component of the phase error in synchronization with the sync pattern detection signal;
a frequency error detector which outputs a difference between a predetermined number and a sampling clock count value during a period of the sync pattern detection signal as a frequency error between a frequency of the RF signal and a frequency of the sampling clock;
a sampling clock generation unit which generates the sampling clock by using a result of adding the low frequency component of the phase error and the frequency error; and
a mode control unit which controls the low pass filter and controls whether to transmit the frequency error, so that the phase locked loop circuit is operated in a frequency pulling-in processing mode if the frequency error is non-zero, or a phase locking processing mode if the frequency error is zero.

20. The phase locked loop circuit of claim 19, further comprising:
a multiplexer which detects either the value zero or the value of the frequency error output from the frequency error detector and transmits the detected value as a signal; and
an integrator which integrates the transmitted signal outputted from the multiplexer so that the transmitted signal is in synchronization with the sync pattern detection signal, and which transmits the integrated signal to the sampling clock generation unit.

21. A phase locked loop circuit in an optical disc reproducing system, comprising:
an analog/digital converter which samples an RF signal read from a disc loaded in the optical disc reproducing system, wherein the RF signal is sampled according to a sampling clock;
a sync pattern detection signal/phase error generation unit which generates a sync pattern detection signal indicating detection of a sync pattern if the sync pattern is detected based on the sampled RF signal output from the analog/digital converter, and which detects and outputs a detected phase error between the sampled RF signal and a zero crossing point of the RF signal based on the sampled RF signal; and
a sampling clock generation unit which generates the sampling clock based on the sync pattern detection signal and the phase error.

22. The phase locked loop circuit of claim 21, further comprising:
a frequency error detector which outputs a difference between a sampling clock count value during a period of the sync pattern detection signal, and a predetermined number, as a frequency error between a frequency of the RF signal and a frequency of a sampling clock.

23. The phase locked loop circuit of claim 22, wherein the sampling clock generation unit further comprises:
an adder which adds the frequency error and the phase error, wherein the predetermined number is a number of sampling clock cycles generated during a period of the sync pattern.

24. A phase locked loop control method comprising:
sampling an input signal according to a sampling clock output by control of the phase locked loop;
generating a pattern detection signal indicating detection of a predetermined pattern;
detecting a phase error and outputting the phase error between the sampled input signal and a zero crossing point of the input signal if the sampled input signal has the predetermined pattern; and
generating the sampling clock output based on the pattern detection signal and the phase error,
wherein the predetermined pattern is uniformly distributed over the entire range in which the input signal can be inputted.

25. The phase locked loop control method of claim 24, wherein the predetermined pattern is a sync pattern.

26. The phase locked loop control method of claim 25, wherein the generating of the pattern detection signal and the phase error comprises:
detecting a zero crossing point of the sampled input signal;
determining whether the sampled input signal has the predetermined pattern by counting cycles of the sampling clock according to the detected zero crossing point;
detecting an absolute difference between the sampled input signals;
checking whether the determination that the sampled input signal has the predetermined pattern is repeatedly performed;
outputting the detected absolute difference as the phase error between the sampled input signal and the zero crossing point of the input signal, if the determination that the sampled input signal has the predetermined pattern is found to be repeatedly performed; and
generating the pattern detection signal at a time point which is delayed by a first predetermined number of sampling clock cycles from the zero crossing point located at the center of the predetermined pattern, if the determination that the sampled input signal has the predetermined pattern is found to be repeatedly performed,
wherein the first predetermined number is constant.

27. The phase locked loop control method of claim 25, further comprising:
detecting the difference between a sampling clock count value during a period of the pattern detection signal and a second predetermined number as a frequency error between the frequency of the input signal and the frequency of the sampling clock;
wherein the generating of the sampling clock comprises adding the frequency error to the phase error,
wherein the second predetermined number is the number of sampling clocks generated during the period of the predetermined pattern, and
wherein the generating of the sampling clock comprises generating the sampling clock by using the result of the added frequency error and phase error.

28. A phase locked loop circuit, comprising:
a sampler which samples an input signal according to a sampling clock output, wherein the sampling clock output is generated by a sampling clock generation unit which generates the sampling clock based on a pattern detection signal and a phase error; and
a pattern detection signal/phase error generation unit which generates the pattern detection signal indicating a detection of a predetermined pattern, detects a phase error between the sampled input signal and a zero crossing point of the input signal if the sampled input signal output from the sampler has the predetermined pattern, and outputs the phase error to the sampling clock generation unit.

29. A phase locked loop circuit, comprising:
a sampling clock generation unit which generates a sampling clock based on a pattern detection signal and a phase error, and transmits the sampling clock to a sampler; and
a pattern detection signal/phase error generation unit which detects the phase error and a frequency error of an RF signal based on a predetermined uniformly distributed pattern, in order to phase lock the RF signal in a high ISI condition.
